(19) United States
(12) Patent Application Publication
(10) Pub. No.: US 2026/0156926 A1
(43) Pub. Date: Jun. 4, 2026

(54) SEMICONDUCTOR DEVICE AND METHOD FOR FABRICATING THE SAME

(71) Applicant: SAMSUNG ELECTRONICS CO., LTD., Suwon-si (KR)

(72) Inventors: Taek Jung KIM, Suwon-si (KR); Hee Chan SONG, Suwon-si (KR); Dong Soo LEE, Suwon-si (KR)

(21) Appl. No.: 19/239,006

(22) Filed: Jun. 16, 2025

(30) Foreign Application Priority Data
Dec. 2, 2024 (KR) 10-2024-0176630

(51) Int. Cl. H10D 84/83; H10D 62/10; H10D 84/01

(52) U.S. Cl. CPC H10D 84/8314; H10D 62/102; H10D 84/013; H10D 84/0135; H10D 84/0144; H10D 84/0147; H10D 84/8316

(57) ABSTRACT

A method for fabricating a semiconductor device is provided. The method for fabricating the semiconductor device includes providing a substrate, forming a first dipole layer on an upper surface of the substrate, etching a portion of the first dipole layer, wherein a remaining the first dipole layer is defined as a second dipole layer, forming a first p-type metal-oxide semiconductor (PMOS) conductive layer on an upper surface of the second dipole layer, forming a second PMOS conductive layer on an upper surface of the first PMOS conductive layer, and forming a fourth PMOS conductive layer by performing an annealing process to transform the second dipole layer between the upper surface of the substrate and a lower surface of the first PMOS conductive layer, wherein the fourth PMOS conductive layer includes a material different from a material of the second dipole layer.

### CROSS-REFERENCE TO RELATED APPLICATION

This application claims priority from Korean Patent Application No. 10-2024-0176630 filed on Dec. 2, 2024, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor device and a method for fabricating the same.

### 2. Description of the Related Art

As the feature size of metal-oxide semiconductor (MOS) transistors decreases, the length of the gates and the length of the channels formed therebelow also decrease. Therefore, various studies are being conducted to increase the capacitance between gates and channels and improve the operating characteristics of MOS transistors.

Additionally, in conventional techniques, the step difference between n-type MOS (NMOS) transistors and p-type MOS (PMOS) transistors has increased, thereby increasing the process difficulty of forming the NMOS transistors and PMOS transistors. To address this, research is being conducted to reduce the step difference between NMOS transistors and PMOS transistors to lower the process difficulty.

### SUMMARY

An objective of the present disclosure is to provide a semiconductor device and a method for fabricating the same that can lower the step difference between a p-type metal-oxide semiconductor (PMOS) gate structure and an n-type metal-oxide semiconductor (NMOS) gate structure by reducing the height of the PMOS gate structure.

The objective to be solved by the present disclosure is not limited to the above-mentioned objectives, and other objectives not explicitly stated will be clearly understood by those skilled in the art from the descriptions below.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a method for fabricating a semiconductor device, comprising providing a substrate, forming a first dipole layer on an upper surface of the substrate, etching a portion of the first dipole layer, wherein a remaining the first dipole layer is defined as a second dipole layer, forming a first p-type metal-oxide semiconductor (PMOS) conductive layer on an upper surface of the second dipole layer, forming a second PMOS conductive layer on an upper surface of the first PMOS conductive layer, and forming a fourth PMOS conductive layer by performing an annealing process to transform the second dipole layer between the upper surface of the substrate and a lower surface of the first PMOS conductive layer, wherein the fourth PMOS conductive layer includes a material different from a material of the second dipole layer.

According to an aspect of the present disclosure, there is provided a method for fabricating a semiconductor device, comprising providing a substrate including an n-type metal-oxide semiconductor (NMOS) region and a p-type metal-oxide semiconductor (PMOS) region, forming a first dipole layer on an upper surface of the substrate in each of the NMOS region and the PMOS region, etching a portion of the first dipole layer in the PMOS region, wherein a remaining the first dipole layer in the PMOS region is defined as a second dipole layer, forming a first NMOS conductive layer on an upper surface of the first dipole layer in the NMOS region, and forming a first PMOS conductive layer on an upper surface of the second dipole layer in the PMOS region, forming a second NMOS conductive layer on an upper surface of the first NMOS conductive layer, and forming a second PMOS conductive layer on an upper surface of the first PMOS conductive layer, and forming a fourth PMOS conductive layer by performing an annealing process to transform the second dipole layer between the upper surface of the substrate and a lower surface of the first PMOS conductive layer, wherein the fourth PMOS conductive layer includes a material different from a material of the second dipole layer, wherein the first NMOS conductive layer and the first PMOS conductive layer include the same material, and wherein the second NMOS conductive layer and the second PMOS conductive layer include the same material.

According to an aspect of the present disclosure, there is provided a semiconductor device, comprising a substrate including an n-type metal-oxide semiconductor (NMOS) region and a p-type metal-oxide semiconductor (PMOS) region, an NMOS gate structure including an NMOS gate insulating layer, a first dipole layer, a first NMOS conductive layer, a second NMOS conductive layer and an NMOS capping layer sequentially stacked in a vertical direction on an upper surface of the substrate in the NMOS region, and a PMOS gate structure including a PMOS gate insulating layer, a fourth PMOS conductive layer, a first PMOS conductive layer, a second PMOS conductive layer and a PMOS capping layer sequentially stacked in the vertical direction on an upper surface of the substrate in the PMOS region, wherein the first NMOS conductive layer and the first PMOS conductive layer include the same material, wherein the second NMOS conductive layer and the second PMOS conductive layer include the same material, wherein a thickness of the fourth PMOS conductive layer in the vertical direction is smaller than a thickness of the first dipole layer in the vertical direction, wherein a thickness of the first PMOS conductive layer in the vertical direction is the same as a thickness of the first NMOS conductive layer in the vertical direction, wherein a thickness of the second PMOS conductive layer in the vertical direction is the same as a thickness of the second NMOS conductive layer in the vertical direction, and wherein an upper surface of the PMOS gate structure is formed lower than an upper surface of the NMOS gate structure.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic layout view of a semiconductor device according to some embodiments of the present disclosure;

FIG. 2 is a cross-sectional view for explaining the semiconductor device according to some embodiments of the present disclosure;

FIGS. 3 to 13 are diagrams illustrating intermediate steps of a method for fabricating a semiconductor device according to some embodiments of the present disclosure;

FIGS. 14 to 19 are diagrams illustrating intermediate steps of a method for fabricating a semiconductor device according to other embodiments of the present disclosure;

FIG. 20 is a cross-sectional view for explaining a semiconductor device according to other embodiments of the present disclosure; and

FIGS. 21 through 27 are diagrams illustrating intermediate steps of a method for fabricating a semiconductor device according to yet other embodiments of the present disclosure.

### DETAILED DESCRIPTION

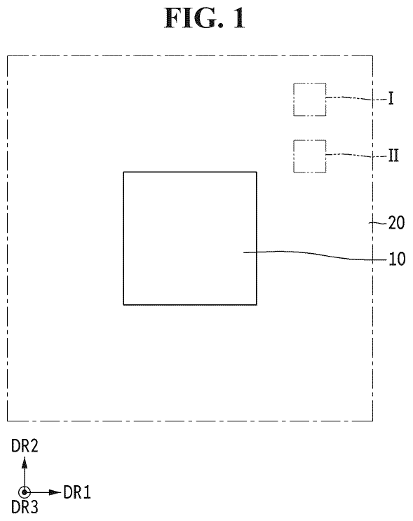

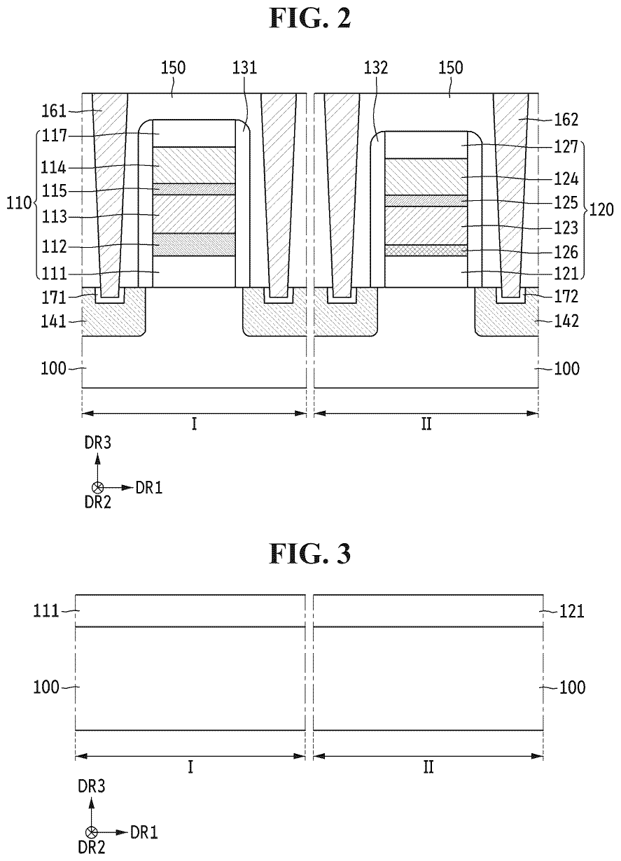

A semiconductor device according to some embodiments of the present disclosure will hereinafter be described with reference to FIGS. 1 and 2.

FIG. 1 is a schematic layout view of a semiconductor device according to some embodiments of the present disclosure. FIG. 2 is a cross-sectional view for explaining the semiconductor device according to some embodiments of the present disclosure.

Referring to FIG. 1, the semiconductor device according to some embodiments of the present disclosure may include a cell region 10 and a peripheral region 20 defined around the cell region 10. For example, a substrate (“100” in FIG. 2) may include the cell region 10 and the peripheral region 20. For example, the cell region 10 may be a region where memory cells are arranged, and the peripheral region 20 may be a region where circuits for operating the memory cells in the cell region 10 are arranged.

FIG. 2 illustrates a cross-sectional view of an NMOS region I and a PMOS region II formed in the peripheral region 20 of FIG. 1. Referring to FIG. 2, the semiconductor device according to some embodiments of the present disclosure includes the substrate 100, an n-type metal-oxide semiconductor (NMOS) gate structure 110, a p-type metal-oxide semiconductor (PMOS) gate structure 120, an NMOS gate spacer 131, a PMOS gate spacer 132, an NMOS source/drain region 141, a PMOS source/drain region 142, an interlayer insulating layer 150, an NMOS contact 161, a PMOS contact 162, an NMOS silicide layer 171, and a PMOS silicide layer 172.

The substrate 100 may be a silicon substrate (Si) or Si-on-insulator (SOI). Alternatively, the substrate 100 may include silicon-germanium (SiGe), SiGe-on-insulator (SGOI), indium antimonide, a lead tellurium compound, indium arsenide, indium phosphide, gallium arsenide, or gallium antimonide, but the present disclosure is not limited thereto. In some embodiments, the substrate 100 may be a bonded form of an Si substrate and a base substrate formed of another material. For example, the base substrate may be formed of one of the aforementioned compound semiconductors, but the present disclosure is not limited thereto.

For example, the substrate 100 may include an NMOS region I and a PMOS region II. The NMOS region I may be a region where an NMOS transistor is formed, and the PMOS region II may be a region where a PMOS transistor is formed. That is, an NMOS transistor may be formed on the surface of the substrate 100 in the NMOS region I, and a PMOS transistor may be formed on the surface of the substrate 100 in the PMOS region II. The upper surfaces of the portions of the substrate 100 in the NMOS region I and the PMOS region II may be formed on the same plane.

In the following description, a first horizontal direction DR1 and a second horizontal direction DR2 may be defined as directions parallel to the upper surface of the substrate 100. The second horizontal direction DR2 may be defined as a direction different from the first horizontal direction DR1. A vertical direction DR3 may be defined as a direction perpendicular to both the first and second horizontal directions DR1 and DR2. That is, the vertical direction DR3 may be defined as a direction perpendicular to the upper surface of the substrate 100.

The NMOS gate structure 110 may be disposed on the upper surface of the portion of the substrate 100 in the NMOS region I. For example, the NMOS gate structure 110 may extend in the second horizontal direction DR2. The NMOS gate structure 110 may include an NMOS gate insulating layer 111, a first dipole layer 112, a first NMOS conductive layer 113, a third NMOS conductive layer 115, a second NMOS conductive layer 114, and an NMOS capping layer 117 sequentially stacked in the vertical direction DR3 on the upper surface of the portion of the substrate 100 in the NMOS region I.

The PMOS gate structure 120 may be disposed on the upper surface of the portion of the substrate 100 in the PMOS region II. For example, the PMOS gate structure 120 may extend in the second horizontal direction DR2. The PMOS gate structure 120 may include a PMOS gate insulating layer 121, a fourth PMOS conductive layer 126, a first PMOS conductive layer 123, a third PMOS conductive layer 125, a second PMOS conductive layer 124, and a PMOS capping layer 127 sequentially stacked in the vertical direction DR3 on the upper surface of the portion of the substrate 100 in the PMOS region II. The upper surface of the PMOS gate structure 120 may be formed lower than the upper surface of the NMOS gate structure 110.

The NMOS gate insulating layer 111 may be disposed in the NMOS region I. The NMOS gate insulating layer 111 may be disposed on the upper surface of the portion of the substrate 100 in the NMOS region I. The lower surface of the NMOS gate insulating layer 111 may contact the upper surface of the substrate 100. For example, the NMOS gate insulating layer 111 may include an interfacial film contacting the upper surface of the substrate 100. The PMOS gate insulating layer 121 may be disposed in the PMOS region II. The PMOS gate insulating layer 121 may be disposed on the upper surface of the portion of the substrate 100 in the PMOS region II. The lower surface of the PMOS gate insulating layer 121 may contact the upper surface of the substrate 100. For example, the PMOS gate insulating layer 121 may include an interfacial film contacting the upper surface of the substrate 100. For example, the thickness of the NMOS gate insulating layer 111 in the vertical direction DR3 and the thickness of the PMOS gate insulating layer 121 in the vertical direction DR3 may be the same. For example, the NMOS gate insulating layer 111 and the PMOS gate insulating layer 121 may include the same material.

Each of the NMOS gate insulating layer 111 and the PMOS gate insulating layer 121 may include at least one of silicon oxide, silicon oxynitride, silicon nitride, or a high-k material with a greater dielectric constant than silicon oxide. The high-k material may include at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some embodiments of the present disclosure may include a negative capacitance (NC) field-effect transistor (FET) utilizing a negative capacitor. For example, each of the NMOS gate insulating layer 111 and the PMOS gate insulating layer 121 may include a ferroelectric material film exhibiting ferroelectric properties and a paraelectric material film exhibiting paraelectric properties.

The ferroelectric material film may exhibit negative capacitance, and the paraelectric material film may exhibit positive capacitance. For example, when two or more capacitors are connected in series, and each capacitor has a positive capacitance value, the total capacitance decreases compared to the capacitance of each individual capacitor. However, if at least one of the capacitances of the capacitors connected in series has a negative value, the total capacitance may have a positive value that is greater than the absolute capacitance of each individual capacitor.

When a ferroelectric material film exhibiting negative capacitance and a paraelectric material film exhibiting positive capacitance are connected in series, the overall capacitance value of the series connection of the ferroelectric material film and the paraelectric material film may increase. By utilizing this increase in the overall capacitance value, a transistor including the ferroelectric material film may achieve a subthreshold swing (SS) of less than 60 mV/decade at room temperature.

The ferroelectric material film may have ferroelectric properties. The ferroelectric material film may include at least one of hafnium oxide, hafnium zirconium oxide, barium strontium titanium oxide, barium titanium oxide, or lead zirconium titanium oxide. Here, the hafnium zirconium oxide may be, for example, a material in which zirconium (Zr) is doped into hafnium oxide (HfO₂). Alternatively, the hafnium zirconium oxide may be a compound of hafnium (Hf), Zr, and oxygen (O).

The ferroelectric material film may further include a dopant. For example, the dopant may include at least one of aluminum (Al), titanium (Ti), niobium (Nb), lanthanum (La), yttrium (Y), magnesium (Mg), Si, calcium (Ca), cerium (Ce), dysprosium (Dy), erbium (Er), gadolinium (Gd), germanium (Ge), scandium (Sc), strontium (Sr), or tin (Sn). The type of dopant included in the ferroelectric material film may vary depending on the ferroelectric material included in the ferroelectric material film.

When the ferroelectric material film includes hafnium oxide, the dopant included in the ferroelectric material film may include at least one of Gd, Si, Zr, Al, or Y.

When the dopant is Al, the ferroelectric material film may include 3 to 8 atomic percent (at%) of Al. Here, the proportion of the dopant may refer to the ratio of Al relative to the total amount of Hf and Al.

When the dopant is Si, the ferroelectric material film may include 2 to 10 at % of Si. When the dopant is Y, the ferroelectric material film may include 2 to 10 at % of Y. When the dopant is Gd, the ferroelectric material film may include 1 to 7 at % of Gd. When the dopant is Zr, the ferroelectric material film may include 50 to 80 at % of Zr.

The paraelectric material film may exhibit paraelectric properties. The paraelectric material film may include at least one of silicon oxide or a metal oxide having a large dielectric constant. The metal oxide included in the paraelectric material film may include, for example, at least one of hafnium oxide, zirconium oxide, or aluminum oxide, but the present disclosure is not limited thereto.

The ferroelectric material film and the paraelectric material film may include the same material. The ferroelectric material film may exhibit ferroelectric properties, the paraelectric material film may not exhibit such ferroelectric properties. For example, when the ferroelectric material film and the paraelectric material film both include hafnium oxide, the crystal structure of hafnium oxide in the ferroelectric material film may differ from that in the paraelectric material film.

The ferroelectric material film may have a thickness that exhibits ferroelectric properties. The thickness of the ferroelectric material film may be, for example, from 0.5 nm to 10 nm, but the present disclosure is not limited thereto. Since the critical thickness for exhibiting ferroelectric properties may vary depending on the ferroelectric material, the thickness of the ferroelectric material film may differ depending on the ferroelectric material.

For example, each of the NMOS gate insulating layer 111 and the PMOS gate insulating layer 121 may include a single ferroelectric material film. In another example, each of the NMOS gate insulating layer 111 and the PMOS gate insulating layer 121 may include a plurality of ferroelectric material films spaced apart from each other. Each of the NMOS gate insulating layer 111 and the PMOS gate insulating layer 121 may have a laminated film structure in which a plurality of ferroelectric material films and a plurality of paraelectric material films are alternately stacked.

The first dipole layer 112 may be disposed in the NMOS region I. The first dipole layer 112 may be disposed on the upper surface of the NMOS gate insulating layer 111. For example, the lower surface of the first dipole layer 112 may contact the upper surface of the NMOS gate insulating layer 111. The first dipole layer 112 may include lanthanum oxide (LaO). In other embodiments, the first dipole layer 112 may include lanthanum oxicarbide (LaOC), lanthanum carbide (LaC), scandium oxide (ScO), scandium oxicarbide (ScOC), scandium carbide (ScC), zirconium oxide (ZrO), zirconium oxicarbide (ZrOC), or zirconium carbide (ZrC).

The fourth PMOS conductive layer 126 may be disposed in the PMOS region II. The fourth PMOS conductive layer 126 may be disposed on the upper surface of the PMOS gate insulating layer 121. For example, the lower surface of the fourth PMOS conductive layer 126 may contact the upper surface of the PMOS gate insulating layer 121. The thickness of the fourth PMOS conductive layer 126 in the vertical direction DR3 may be smaller than the thickness of the first dipole layer 112 in the vertical direction DR3. For example, the lower surface of the fourth PMOS conductive layer 126 may be formed on the same plane as the lower surface of the first dipole layer 112. The upper surface of the fourth PMOS conductive layer 126 may be formed lower than the upper surface of the first dipole layer 112.

For example, the fourth PMOS conductive layer 126 may be formed by performing a nitriding process on the first dipole layer 112. For example, the fourth PMOS conductive layer 126 may include lanthanum oxynitride (LaON). In other embodiments, the fourth PMOS conductive layer 126 may include lanthanum oxicarbonitride (LaOCN), lanthanum carbonitride (LaCN), scandium oxynitride (ScON), scandium oxicarbonitride (ScOCN), scandium carbonitride (ScCN), zirconium oxynitride (ZrON), zirconium oxicarbonitride (ZrOCN), or zirconium carbonitride (ZrCN).

The first NMOS conductive layer 113 may be disposed in the NMOS region I. The first NMOS conductive layer 113 may be disposed on the upper surface of the first dipole layer 112. For example, the lower surface of the first NMOS conductive layer 113 may contact the upper surface of the first dipole layer 112. For example, the first NMOS conductive layer 113 may include a metal nitride or a metal oxynitride. For example, the metal included in the first NMOS conductive layer 113 may include at least one of Ti, Al, tungsten (W), molybdenum (Mo), or La.

The first PMOS conductive layer 123 may be disposed in the PMOS region II. The first PMOS conductive layer 123 may be disposed on the upper surface of the fourth PMOS conductive layer 126. For example, the lower surface of the first PMOS conductive layer 123 may contact the upper surface of the fourth PMOS conductive layer 126. For example, the thickness of the first PMOS conductive layer 123 in the vertical direction DR3 may be the same as the thickness of the first NMOS conductive layer 113 in the vertical direction DR3. For example, the lower surface of the first PMOS conductive layer 123 may be formed lower than the lower surface of the first NMOS conductive layer 113. For example, the upper surface of the first PMOS conductive layer 123 may be formed lower than the upper surface of the first NMOS conductive layer 113. For example, the first PMOS conductive layer 123 may include the same material as the first NMOS conductive layer 113.

The third NMOS conductive layer 115 may be disposed in the NMOS region I. The third NMOS conductive layer 115 may be disposed on the upper surface of the first NMOS conductive layer 113. For example, the lower surface of the third NMOS conductive layer 115 may contact the upper surface of the first NMOS conductive layer 113. For example, the third NMOS conductive layer 115 may include a metal silicon oxide. For example, the third NMOS conductive layer 115 may include lanthanum silicon oxide (LaSiO) or aluminum silicon oxide (AlSiO).

The third PMOS conductive layer 125 may be disposed in the PMOS region II. The third PMOS conductive layer 125 may be disposed on the upper surface of the first PMOS conductive layer 123. For example, the lower surface of the third PMOS conductive layer 125 may contact the upper surface of the first PMOS conductive layer 123. For example, the thickness of the third PMOS conductive layer 125 in the vertical direction DR3 may be the same as the thickness of the third NMOS conductive layer 115 in the vertical direction DR3. For example, the lower surface of the third PMOS conductive layer 125 may be formed lower than the lower surface of the third NMOS conductive layer 115. For example, the upper surface of the third PMOS conductive layer 125 may be formed lower than the upper surface of the third NMOS conductive layer 115. For example, the third PMOS conductive layer 125 may include the same material as the third NMOS conductive layer 115.

The second NMOS conductive layer 114 may be disposed in the NMOS region I. The second NMOS conductive layer 114 may be disposed on the upper surface of the third NMOS conductive layer 115. For example, the lower surface of the second NMOS conductive layer 114 may contact the upper surface of the third NMOS conductive layer 115. For example, the second NMOS conductive layer 114 may include polycrystalline silicon (poly-Si). In other embodiments, the second NMOS conductive layer 114 may include a metal nitride.

The second PMOS conductive layer 124 may be disposed in the PMOS region II. The second PMOS conductive layer 124 may be disposed on the upper surface of the third PMOS conductive layer 125. For example, the lower surface of the second PMOS conductive layer 124 may contact the upper surface of the third PMOS conductive layer 125. For example, the thickness of the second PMOS conductive layer 124 in the vertical direction DR3 may be the same as the thickness of the second NMOS conductive layer 114 in the vertical direction DR3. For example, the lower surface of the second PMOS conductive layer 124 may be formed lower than the lower surface of the second NMOS conductive layer 114. For example, the upper surface of the second PMOS conductive layer 124 may be formed lower than the upper surface of the second NMOS conductive layer 114. For example, the second PMOS conductive layer 124 may include the same material as the second NMOS conductive layer 114.

The NMOS capping layer 117 may be disposed in the NMOS region I. The NMOS capping layer 117 may be disposed on the upper surface of the second NMOS conductive layer 114. For example, the lower surface of the NMOS capping layer 117 may contact the upper surface of the second NMOS conductive layer 114. For example, the NMOS capping layer 117 may include an insulating material. For example, the NMOS capping layer 117 may include at least one of silicon nitride (SiN), silicon oxynitride (SiON), silicon oxide (SiO₂), silicon carbonitride (SiCN), silicon oxycarbonitride (SiOCN), or a combination thereof.

The PMOS capping layer 127 may be disposed in the PMOS region II. The PMOS capping layer 127 may be disposed on the upper surface of the second PMOS conductive layer 124. For example, the lower surface of the PMOS capping layer 127 may contact the upper surface of the second PMOS conductive layer 124. The thickness of the PMOS capping layer 127 in the vertical direction DR3 may be the same as that of the NMOS capping layer 117 in the vertical direction DR3. The lower surface of the PMOS capping layer 127 may be formed lower than the lower surface of the NMOS capping layer 117. The upper surface of the PMOS capping layer 127 may be formed lower than the upper surface of the NMOS capping layer 117. For example, the PMOS capping layer 127 may include the same material as the NMOS capping layer 117.

The NMOS gate spacer 131 may be disposed on the upper surface of the portion of the substrate 100 in the NMOS region I. The NMOS gate spacer 131 may be disposed on both sidewalls of the NMOS gate structure 110 in the first horizontal direction DR1. The NMOS gate spacer 131 may extend in the second horizontal direction DR2. For example, the NMOS gate spacer 131 may contact the sidewalls of the NMOS gate insulating layer 111, the first dipole layer 112, the first NMOS conductive layer 113, the third NMOS conductive layer 115, the second NMOS conductive layer 114, and the NMOS capping layer 117 in the first horizontal direction DR1. For example, the NMOS gate spacer 131 may include at least one of SiN, SiON, SiO₂, SiOCN, silicon boron nitride (SiBN), silicon oxyboron nitride (SiOBN), silicon oxycarbide (SiOC), or a combination thereof, but the present disclosure is not limited thereto.

The PMOS gate spacer 132 may be disposed on the upper surface of the portion of the substrate 100 in the PMOS region II. The PMOS gate spacer 132 may be disposed on both sidewalls of the PMOS gate structure 120 in the first horizontal direction DR1. The PMOS gate spacer 132 may extend in the second horizontal direction DR2. For example, the PMOS gate spacer 132 may contact the sidewalls, in the first horizontal direction DR1, of each of the PMOS gate insulating layer 121, the fourth PMOS conductive layer 126, the first PMOS conductive layer 123, the third PMOS conductive layer 125, the second PMOS conductive layer 124, and the PMOS capping layer 127. For example, the upper surface of the PMOS gate spacer 132 may be formed lower than the upper surface of the NMOS gate spacer 131. For example, the PMOS gate spacer 132 may include the same material as the NMOS gate spacer 131.

The NMOS source/drain region 141 may be disposed inside the portion of the substrate 100 in the NMOS region I. The NMOS source/drain region 141 may be disposed on both sides of the NMOS gate structure 110 in the first horizontal direction DR1. The PMOS source/drain region 142 may be disposed inside the portion of the substrate 100 in the PMOS region II. The PMOS source/drain region 142 may be disposed on both sides of the PMOS gate structure 120 in the first horizontal direction DR1.

The interlayer insulating layer 150 may be disposed on the upper surfaces of the portions of the substrate 100 in the NMOS region I and the PMOS region II. The interlayer insulating layer 150 may cover the upper surface of each of the NMOS source/drain region 141 and the PMOS source/drain region 142. The interlayer insulating layer 150 may surround the sidewalls of each of the NMOS gate spacer 131 and the PMOS gate spacer 132. The interlayer insulating layer 150 may cover the upper surface of each of the NMOS gate structure 110 and the PMOS gate structure 120. For example, the interlayer insulating layer 150 may include at least one of silicon oxide, silicon nitride, silicon oxynitride, or a low-k material.

The NMOS contact 161 may be disposed in the NMOS region I. The NMOS contact 161 may penetrate the interlayer insulating layer 150 in the vertical direction DR3 and be electrically connected to the NMOS source/drain region 141. The PMOS contact 162 may be disposed in the PMOS region II. The PMOS contact 162 may penetrate the interlayer insulating layer 150 in the vertical direction DR3 and be electrically connected to the PMOS source/drain region 142. For example, the upper surface of each of the NMOS contact 161 and the PMOS contact 162 may be formed on the same plane as the upper surface of the interlayer insulating layer 150, but the present disclosure is not limited thereto. The NMOS contact 161 and the PMOS contact 162 may include a conductive material.

The NMOS silicide layer 171 may be disposed along the interface between the NMOS source/drain region 141 and the NMOS contact 161. The PMOS silicide layer 172 may be disposed along the interface between the PMOS source/drain region 142 and the PMOS contact 162. For example, each of the NMOS silicide layer 171 and the PMOS silicide layer 172 may include a metal silicide.

A method for fabricating a semiconductor device according to some embodiments of the present disclosure will hereinafter be described with reference to FIGS. 2 through 13.

FIGS. 3 through 13 are diagrams illustrating intermediate steps of a method for fabricating a semiconductor device according to some embodiments of the present disclosure.

Referring to FIG. 3, a substrate 100 including an NMOS region I and a PMOS region II may be provided. Thereafter, an NMOS gate insulating layer 111 may be formed on the upper surface of the portion of the substrate 100 in the NMOS region I. Additionally, a PMOS gate insulating layer 121 may be formed on the upper surface of the portion of the substrate 100 in the PMOS region II. For example, each of the NMOS gate insulating layer 111 and the PMOS gate insulating layer 121 may be formed conformally. For example, the NMOS gate insulating layer 111 and the PMOS gate insulating layer 121 may be formed through the same fabricating process. For example, the thickness of the NMOS gate insulating layer 111 in the vertical direction DR3 may be the same as the thickness of the PMOS gate insulating layer 121 in the vertical direction DR3. For example, the upper surface of the NMOS gate insulating layer 111 may be formed on the same plane as the upper surface of the PMOS gate insulating layer 121.

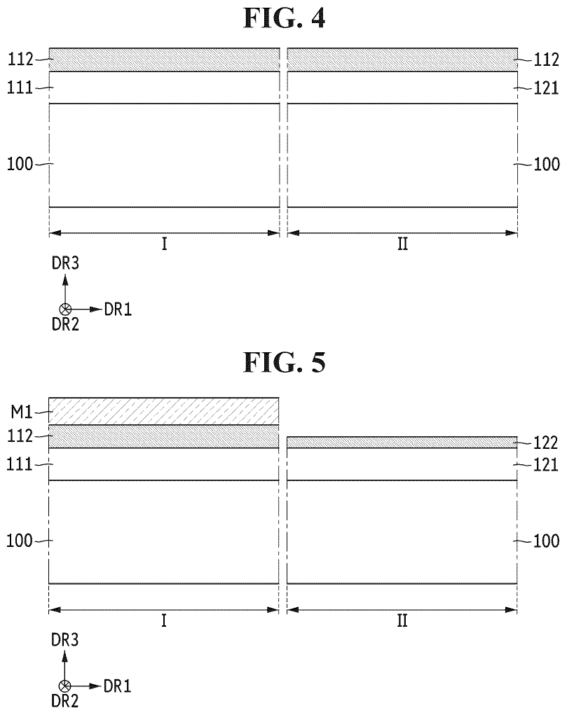

Referring to FIG. 4, a first dipole layer 112 may be formed on the upper surfaces of the portions of the substrate 100 in the NMOS region I and the PMOS region II. For example, the first dipole layer 112 may be formed on the upper surfaces of the NMOS gate insulating layer 111 and the PMOS gate insulating layer 121. For example, the lower surface of the first dipole layer 112 may contact the upper surfaces of the NMOS gate insulating layer 111 and the PMOS gate insulating layer 121. For example, the thickness, in the vertical direction DR3, of the portion of the first dipole layer 112 formed on the upper surface of the NMOS gate insulating layer 111 may be the same as the thickness, in the vertical direction DR3, of the portion of the first dipole layer 112 formed on the upper surface of the PMOS gate insulating layer 121. For example, the first dipole layer 112 may be formed conformally.

For example, the first dipole layer 112 may include LaO. In other embodiments, the first dipole layer 112 may include LaOC, LaC, ScO, ScOC, ScC, ZrO, ZrOC, or ZrC.

Referring to FIG. 5, a first mask pattern M1 may be formed on the upper surface of the portion of the first dipole layer 112 in the NMOS region I. For example, the first mask pattern M1 may expose the upper surface of the portion of the first dipole layer 112 in the PMOS region II. Thereafter, using the first mask pattern M1 as a mask, the portion of the first dipole layer 112 in the PMOS region II may be partially etched. After completing this etching process, the remaining first dipole layer 112 in the PMOS region II may be defined as a second dipole layer 122. For example, the thickness of the second dipole layer 122 in the vertical direction DR3 is smaller than the thickness of the first dipole layer 112 in the vertical direction DR3. For example, the upper surface of the second dipole layer 122 may be formed lower than the upper surface of the first dipole layer 112. For example, the second dipole layer 122 may include the same material as the first dipole layer 112.

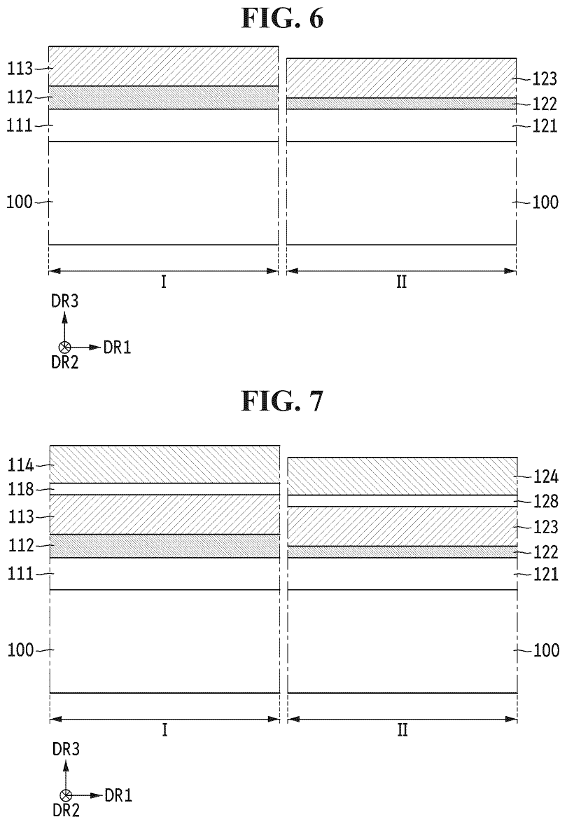

Referring to FIG. 6, the first mask pattern M1 of FIG. 5 may be removed. Thereafter, a first NMOS conductive layer 113 may be formed on the upper surface of the first dipole layer 112. Additionally, a first PMOS conductive layer 123 may be formed on the upper surface of the second dipole layer 122. For example, the lower surface of the first NMOS conductive layer 113 may contact the upper surface of the first dipole layer 112. Similarly, the lower surface of the first PMOS conductive layer 123 may contact the upper surface of the second dipole layer 122. For example, each of the first NMOS conductive layer 113 and the first PMOS conductive layer 123 may be formed conformally. For example, the first NMOS conductive layer 113 and the first PMOS conductive layer 123 may be formed through the same fabricating process.

For example, the thickness of the first NMOS conductive layer 113 in the vertical direction DR3 may be the same as the thickness of the first PMOS conductive layer 123 in the vertical direction DR3. For example, the upper surface of the first PMOS conductive layer 123 may be formed lower than the upper surface of the first NMOS conductive layer 113. For example, the first NMOS conductive layer 113 and the first PMOS conductive layer 123 may include the same material. For example, each of the first NMOS conductive layer 113 and the first PMOS conductive layer 123 may include a metal nitride or a metal oxynitride. For example, the metal included in each of the first NMOS conductive layer 113 and the first PMOS conductive layer 123 may include at least one of Ti, Al, W, Mo, or La.

Referring to FIG. 7, an NMOS sacrificial layer 118 and a second NMOS conductive layer 114 may be sequentially formed on the upper surface of the first NMOS conductive layer 113. For example, the lower surface of the NMOS sacrificial layer 118 may contact the upper surface of the first NMOS conductive layer 113. For example, the lower surface of the second NMOS conductive layer 114 may contact the upper surface of the NMOS sacrificial layer 118. For example, each of the NMOS sacrificial layer 118 and the second NMOS conductive layer 114 may be formed conformally. Similarly, a PMOS sacrificial layer 128 and a second PMOS conductive layer 124 may be sequentially formed on the upper surface of the first PMOS conductive layer 123. For example, the lower surface of the PMOS sacrificial layer 128 may contact the upper surface of the PMOS conductive layer 123. For example, the lower surface of the second PMOS conductive layer 124 may contact the upper surface of the PMOS sacrificial layer 128. For example, the PMOS sacrificial layer 128 and the second PMOS conductive layer 124 may be formed conformally.

For example, the NMOS sacrificial layer 118 and the PMOS sacrificial layer 128 may be formed through the same fabricating process. For example, the thickness of the NMOS sacrificial layer 118 in the vertical direction DR3 may be the same as the thickness of the PMOS sacrificial layer 128 in the vertical direction DR3. For example, the upper surface of the PMOS sacrificial layer 128 may be formed lower than the upper surface of the NMOS sacrificial layer 118. For example, the NMOS sacrificial layer 118 and the PMOS sacrificial layer 128 may include the same material. For example, each of the NMOS sacrificial layer 118 and the PMOS sacrificial layer 128 may include La₂O₃. In other embodiments, the NMOS sacrificial layer 118 and the PMOS sacrificial layer 128 may include Al₂O₃.

For example, the second NMOS conductive layer 114 and the second PMOS conductive layer 124 may be formed through the same fabricating process. For example, the thickness of the second NMOS conductive layer 114 in the vertical direction DR3 may be the same as the thickness of the second PMOS conductive layer 124 in the vertical direction DR3. For example, the upper surface of the second PMOS conductive layer 124 may be formed lower than the upper surface of the second NMOS conductive layer 114. For example, the second NMOS conductive layer 114 and the second PMOS conductive layer 124 may include the same material. For example, each of the second NMOS conductive layer 114 and the second PMOS conductive layer 124 may include Poly Si. In other embodiments, each of the second NMOS conductive layer 114 and the second PMOS conductive layer 124 may include a metal nitride.

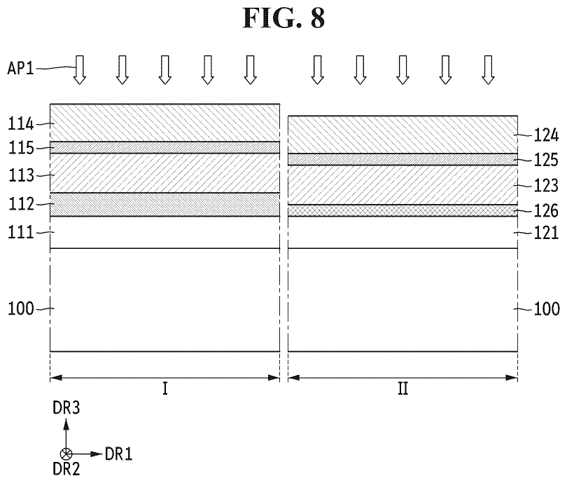

Referring to FIG. 8, an annealing process AP1 may be performed on each of the NMOS region I and the PMOS region II. Through the annealing process AP1, a fourth PMOS conductive layer 126 may be formed between the upper surface of the PMOS gate insulating layer 121 and the lower surface of the first PMOS conductive layer 123. For example, through the annealing process AP1, the second dipole layer 122 of FIG. 7 may be transformed into the fourth PMOS conductive layer 126. The second dipole layer 122 may be nitrided through the annealing process AP1 and converted into the fourth PMOS conductive layer 126. For example, the fourth PMOS conductive layer 126 may include a different material from the second dipole layer 122.

For example, during the annealing process AP1, the portion of the first dipole layer 112 in the NMOS region I may not be transformed because the thickness of the first dipole layer 112 in the vertical direction DR3 is greater than the thickness of the second dipole layer 122 in the vertical direction DR3.

Through the annealing process AP1, a third NMOS conductive layer 115 may be formed between the upper surface of the first NMOS conductive layer 113 and the lower surface of the second NMOS conductive layer 114. Additionally, through the annealing process AP1, a third PMOS conductive layer 125 may be formed between the upper surface of the first PMOS conductive layer 123 and the lower surface of the second PMOS conductive layer 124. For example, through the annealing process AP1, the NMOS sacrificial layer 118 may be transformed into the third NMOS conductive layer 115, and the PMOS sacrificial layer 128 may be transformed into the third PMOS conductive layer 125. For example, the NMOS sacrificial layer 118 may be silicided and transformed into the third NMOS conductive layer 115, and the PMOS sacrificial layer 128 may be silicided and transformed into the third PMOS conductive layer 125. For example, the third NMOS conductive layer 115 and the third PMOS conductive layer 125 may include a different material from the NMOS sacrificial layer 118 and the PMOS sacrificial layer 128, respectively.

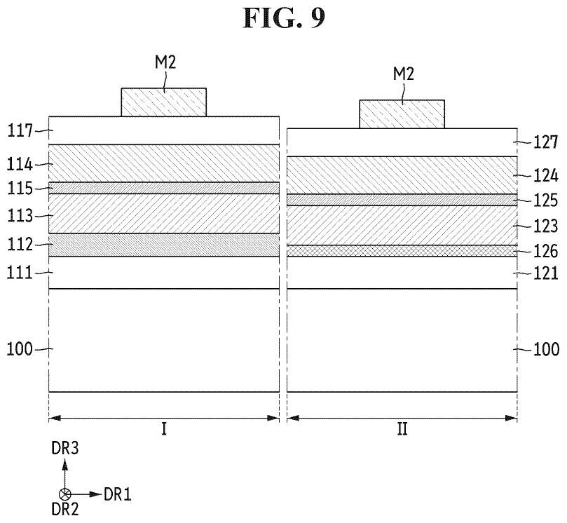

Referring to FIG. 9, an NMOS capping layer 117 may be formed on the upper surface of the second NMOS conductive layer 114. Additionally, a PMOS capping layer 127 may be formed on the upper surface of the second PMOS conductive layer 124. For example, the lower surface of the NMOS capping layer 117 may contact the upper surface of the second NMOS conductive layer 114, and the lower surface of the PMOS capping layer 127 may contact the upper surface of the second PMOS conductive layer 124. For example, each of the NMOS capping layer 117 and the PMOS capping layer 127 may be formed conformally. For example, the NMOS capping layer 117 and the PMOS capping layer 127 may be formed through the same fabricating process.

For example, the thickness of the NMOS capping layer 117 in the vertical direction DR3 may be the same as the thickness of the PMOS capping layer 127 in the vertical direction DR3. For example, the upper surface of the PMOS capping layer 127 may be formed lower than the upper surface of the NMOS capping layer 117. For example, the NMOS capping layer 117 and the PMOS capping layer 127 may include the same material. For example, each of the NMOS capping layer 117 and the PMOS capping layer 127 may include at least one of SiN, SiON, SiO₂, SiCN, SiOCN, or a combination thereof. Thereafter, a second mask pattern M2 may be formed on the upper surfaces of the NMOS capping layer 117 and the PMOS capping layer 127.

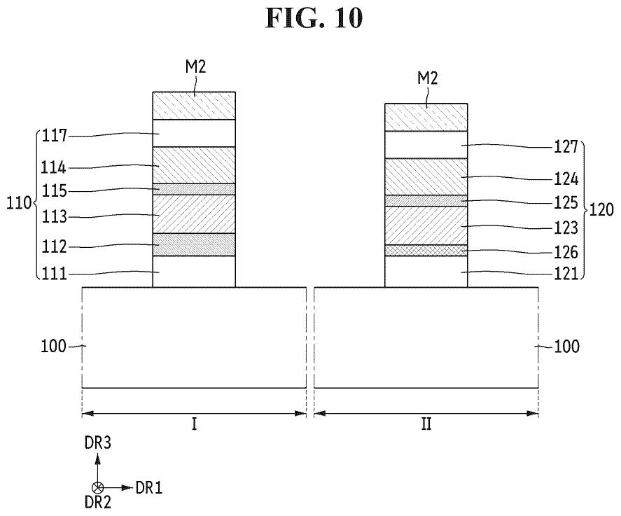

Referring to FIG. 10, a patterning process that involves an etching process using the second mask pattern M2 as a mask may be performed. For example, in the NMOS region I, the NMOS gate insulating layer 111, the first dipole layer 112, the first NMOS conductive layer 113, the third NMOS conductive layer 115, the second NMOS conductive layer 114, and the NMOS capping layer 117 may be patterned using the second mask pattern M2 as a mask. As a result, an NMOS gate structure 110 including the NMOS gate insulating layer 111, the first dipole layer 112, the first NMOS conductive layer 113, the third NMOS conductive layer 115, the second NMOS conductive layer 114, and the NMOS capping layer 117 may be formed on the upper surface of the portion of the substrate 100 in the NMOS region I.

Additionally, in the PMOS region II, the PMOS gate insulating layer 121, the fourth PMOS conductive layer 126, the first PMOS conductive layer 123, the third PMOS conductive layer 125, the second PMOS conductive layer 124, and the PMOS capping layer 127 may be patterned using the second mask pattern M2 as a mask. As a result, a PMOS gate structure 120 including the PMOS gate insulating layer 121, the fourth PMOS conductive layer 126, the first PMOS conductive layer 123, the third PMOS conductive layer 125, the second PMOS conductive layer 124, and the PMOS capping layer 127 may be formed on the upper surface of the portion of the substrate 100 in the PMOS region II. For example, the upper surface of the PMOS gate structure 120 may be formed lower than the upper surface of the NMOS gate structure 110.

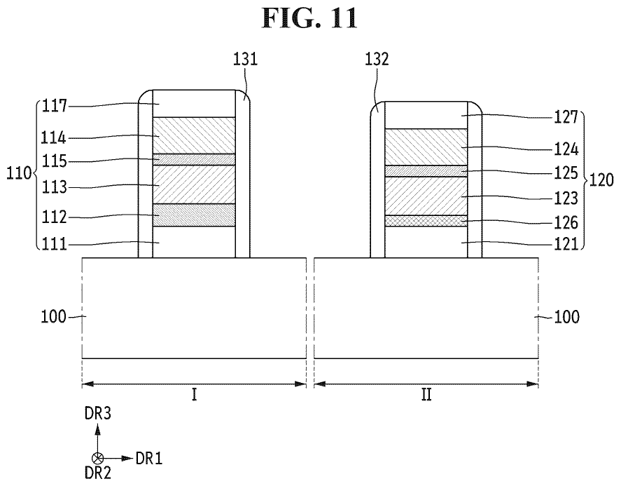

Referring to FIG. 11, the second mask pattern M2 of FIG. 10 may be removed. Thereafter, an NMOS gate spacer 131 may be formed on both sidewalls of the NMOS gate structure 110 in the first horizontal direction DR1. In addition, a PMOS gate spacer 132 may be formed on both sidewalls of the PMOS gate structure 120 in the first horizontal direction DR1. For example, the upper surface of the PMOS gate spacer 132 may be formed lower than the upper surface of the NMOS gate spacer 131. For example, the NMOS gate spacer 131 and the PMOS gate spacer 132 may each include at least one of SiN, SiON, SiO₂, SiOCN, SiBN, SiOBN, SiOC, or a combination thereof, but the present disclosure is not limited thereto.

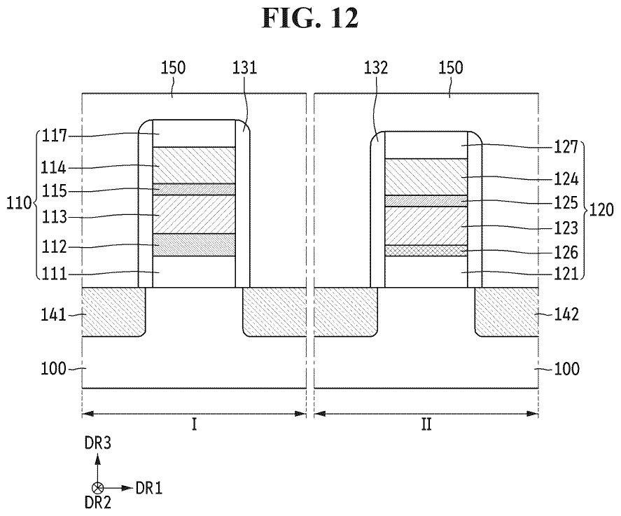

Referring to FIG. 12, an NMOS source/drain region 141 may be formed inside the portion of the substrate 100 in the NMOS region I. The NMOS source/drain region 141 may be formed on both sides of the NMOS gate structure 110 in the first horizontal direction DR1. Similarly, a PMOS source/drain region 142 may be formed inside the portion of the substrate 100 in the PMOS region II. The PMOS source/drain region 142 may be formed on both sides of the PMOS gate structure 120 in the first horizontal direction DR1.

Thereafter, an interlayer insulating layer 150 may be formed on the upper surfaces of the portions of the substrate 100 in the NMOS region I and the PMOS region II. For example, the interlayer insulating layer 150 may cover the upper surfaces of the NMOS source/drain region 141 and the PMOS source/drain region 142. The interlayer insulating layer 150 may surround the sidewalls of the NMOS gate spacer 131 and the PMOS gate spacer 132. The interlayer insulating layer 150 may also cover the upper surfaces of the NMOS gate structure 110 and the PMOS gate structure 120. For example, the interlayer insulating layer 150 may include at least one of silicon oxide, silicon nitride, silicon oxynitride, or a low-k material.

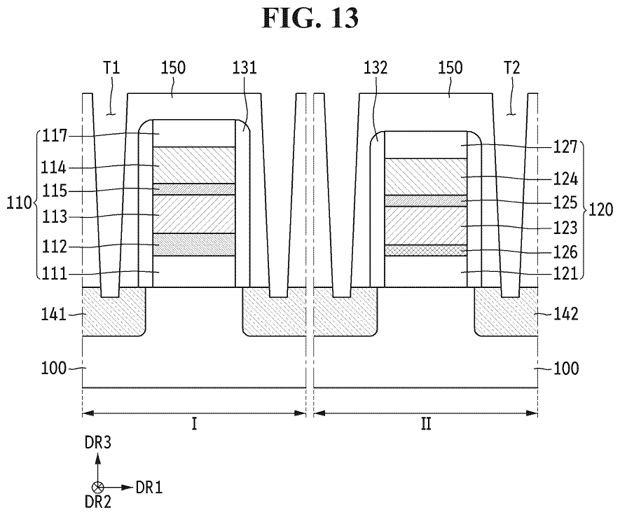

Referring to FIG. 13, an NMOS contact trench T1, which exposes the NMOS source/drain region 141, may be formed by vertically penetrating the portion of the interlayer insulating layer 150 in the NMOS region I. Similarly, a PMOS contact trench T2, which exposes the PMOS source/drain region 142, may be formed by vertically penetrating the portion of the interlayer insulating layer 150 in the PMOS region II.

Referring again to FIG. 2, an NMOS contact 161 may be formed inside the NMOS contact trench T1 of FIG. 13, and a PMOS contact 162 may be formed inside the PMOS contact trench T2 of FIG. 13. In addition, an NMOS silicide layer 171 may be formed along the interface between the NMOS source/drain region 141 and the NMOS contact 161, and a PMOS silicide layer 172 may be formed along the interface between the PMOS source/drain region 142 and the PMOS contact 162. Through these fabricating processes, the semiconductor device illustrated in FIG. 2 may be fabricated.

The method for fabricating a semiconductor device according to some embodiments of the present disclosure may include forming the first dipole layer 112 in both the NMOS region I and the PMOS region II, and then etching the portion of the first dipole layer 112 in the PMOS region II to form the second dipole layer 122. Through a subsequent annealing process AP1, the first dipole layer 112 in the NMOS region I, which has a relatively larger thickness, may remain untransformed, and the second dipole layer 122 in the PMOS region II, which has a relatively smaller thickness, may be transformed to form the fourth PMOS conductive layer 126 in the PMOS region II.

That is, the method for fabricating a semiconductor device according to some embodiments of the present disclosure may selectively form the fourth PMOS conductive layer 126 only in the PMOS region II by modifying the existing second dipole layer 122 through the annealing process AP1, without additionally stacking another conductive layer in the PMOS region II. Accordingly, the method for fabricating a semiconductor device according to some embodiments of the present disclosure may reduce the height of the PMOS gate structure 120 formed in the PMOS region II. In the semiconductor device obtained by the method for fabricating a semiconductor device according to some embodiments of the present disclosure, the upper surface of the PMOS gate structure 120 disposed in the PMOS region II may be formed lower than the upper surface of the NMOS gate structure 110 disposed in the NMOS region I.

A method for fabricating a semiconductor device according to other embodiments of the present disclosure will hereinafter be described with reference to FIGS. 2 and 14 through 19, focusing on differences from the method illustrated in FIGS. 3 through 13.

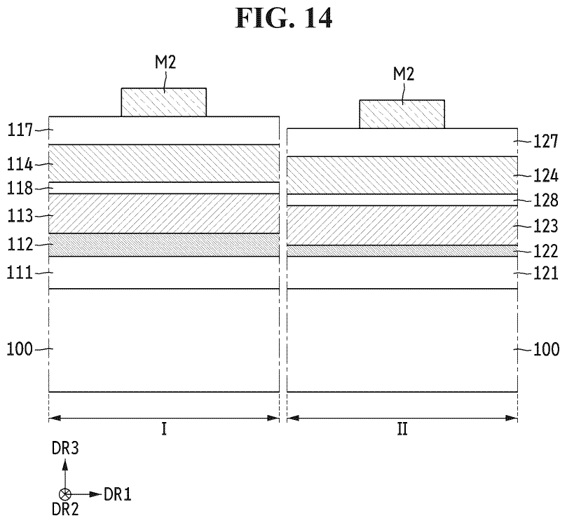

Referring to FIG. 14, after performing the fabricating processes illustrated in FIGS. 3 through 7, an NMOS capping layer 117 may be formed on the upper surface of the second NMOS conductive layer 114. Additionally, a PMOS capping layer 127 may be formed on the upper surface of the second PMOS conductive layer 124. Thereafter, a second mask pattern M2 may be formed on the upper surfaces of the NMOS capping layer 117 and the PMOS capping layer 127.

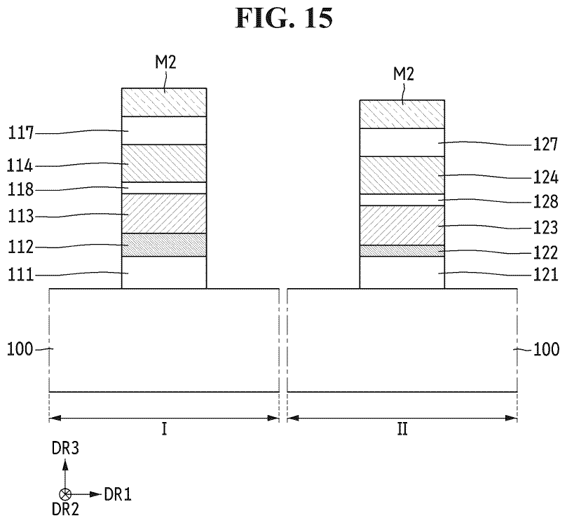

Referring to FIG. 15, a patterning process involving an etching process using the second mask pattern M2 as a mask may be performed. For example, in the NMOS region I, the NMOS gate insulating layer 111, the first dipole layer 112, the first NMOS conductive layer 113, the NMOS sacrificial layer 118, the second NMOS conductive layer 114, and the NMOS capping layer 117 may each be patterned using the second mask pattern M2 as a mask. Additionally, in the PMOS region II, the PMOS gate insulating layer 121, the second dipole layer 122, the first PMOS conductive layer 123, the PMOS sacrificial layer 128, the second PMOS conductive layer 124, and the PMOS capping layer 127 may each be patterned using the second mask pattern M2 as a mask.

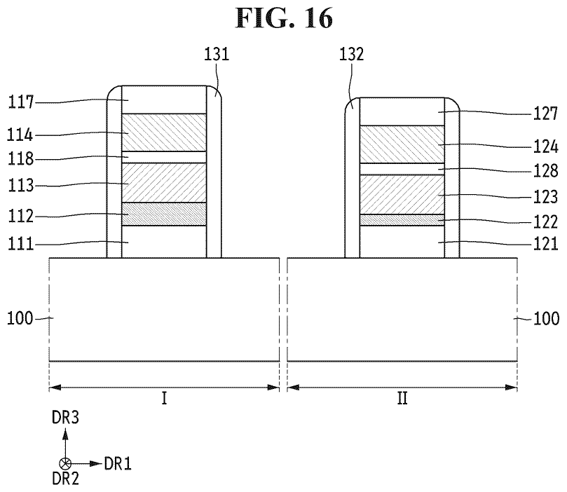

Referring to FIG. 16, the second mask pattern M2 of FIG. 15 may be removed. Thereafter, an NMOS gate spacer 131 may be formed on both sidewalls of each of the NMOS gate insulating layer 111, the first dipole layer 112, the first NMOS conductive layer 113, the NMOS sacrificial layer 118, the second NMOS conductive layer 114, and the NMOS capping layer 117 in the first horizontal direction DR1. Similarly, a PMOS gate spacer 132 may be formed on both sidewalls of each of the PMOS gate insulating layer 121, the second dipole layer 122, the first PMOS conductive layer 123, the PMOS sacrificial layer 128, the second PMOS conductive layer 124, and the PMOS capping layer 127 in the first horizontal direction DR1.

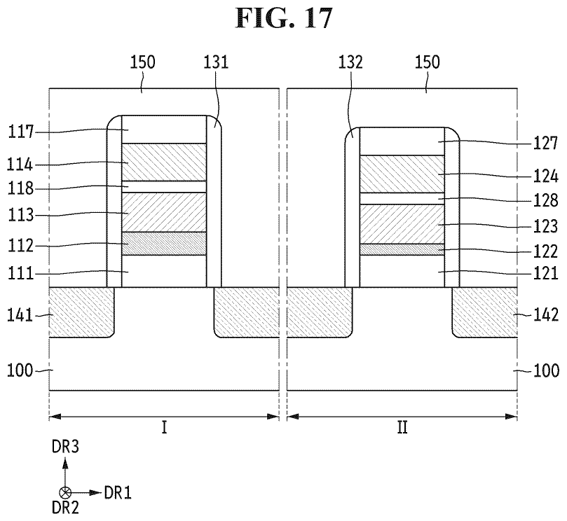

Referring to FIG. 17, an NMOS source/drain region 141 may be formed inside the portion of the substrate 100 in the NMOS region I. The NMOS source/drain region 141 may be formed on both sides of the NMOS gate spacer 131 in the first horizontal direction DR1. Similarly, a PMOS source/drain region 142 may be formed inside the portion of the substrate 100 in the PMOS region II. The PMOS source/drain region 142 may be formed on both sides of the PMOS gate spacer 132 in the first horizontal direction DR1.

Thereafter, an interlayer insulating layer 150 may be formed on the upper surfaces of the portions of the substrate 100 in the NMOS region I and the PMOS region II. For example, the interlayer insulating layer 150 may cover the upper surface of each of the NMOS source/drain region 141 and the PMOS source/drain region 142. The interlayer insulating layer 150 may surround the sidewalls of each of the NMOS gate spacer 131 and the PMOS gate spacer 132. The interlayer insulating layer 150 may also cover the upper surface of each of the NMOS capping layer 117 and the PMOS capping layer 127.

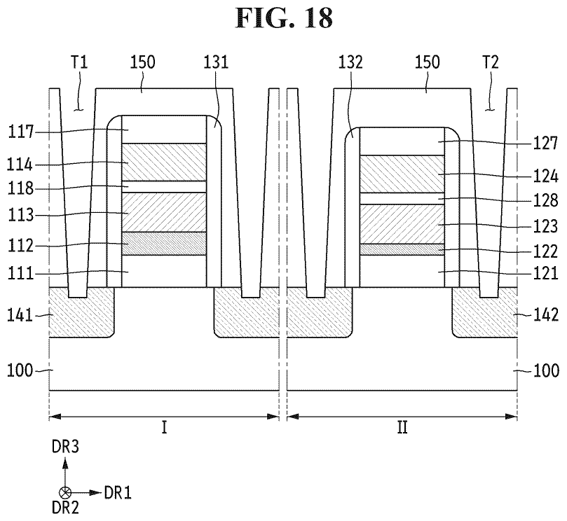

Referring to FIG. 18, an NMOS contact trench T1, which exposes the NMOS source/drain region 141, may be formed by vertically penetrating the portion of the interlayer insulating layer 150 in the NMOS region I. Similarly, a PMOS contact trench T2, which exposes the PMOS source/drain region 142, may be formed by vertically penetrating the portion of the interlayer insulating layer 150 in the PMOS region II.

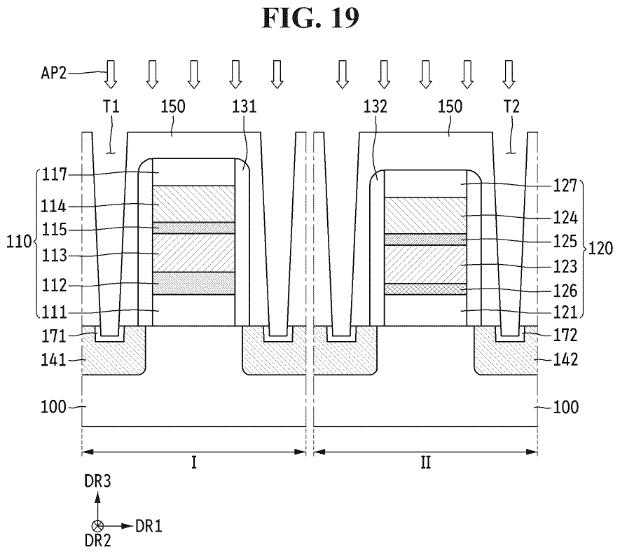

Referring to FIG. 19, an annealing process AP2 may be performed on the NMOS region I and the PMOS region II. Through the annealing process AP2, a portion of the NMOS source/drain region 141 exposed in the NMOS contact trench T1 may be silicided to form an NMOS silicide layer 171, and a portion of the PMOS source/drain region 142 exposed in the PMOS contact trench T2 may be silicided to form a PMOS silicide layer 172.

Additionally, through the annealing process AP2, a fourth PMOS conductive layer 126 may be formed between the upper surface of the PMOS gate insulating layer 121 and the lower surface of the first PMOS conductive layer 123. For example, through the annealing process AP2, the second dipole layer 122 of FIG. 18 may be transformed into the fourth PMOS conductive layer 126. Furthermore, through the annealing process AP2, a third NMOS conductive layer 115 may be formed between the upper surface of the first NMOS conductive layer 113 and the lower surface of the second NMOS conductive layer 114. Additionally, a third PMOS conductive layer 125 may be formed between the upper surface of the first PMOS conductive layer 123 and the lower surface of the second PMOS conductive layer 124. For example, through the annealing process AP2, the NMOS sacrificial layer 118 of FIG. 18 may be transformed into the third NMOS conductive layer 115, and the PMOS sacrificial layer 128 of FIG. 18 may be transformed into the third PMOS conductive layer 125.

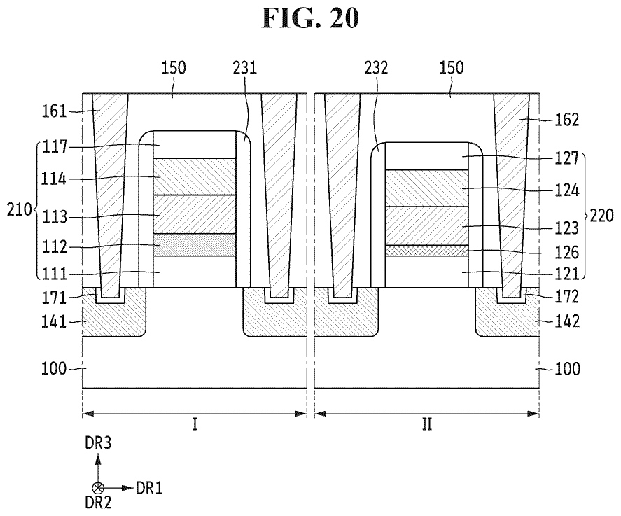

Referring again to FIG. 2, an NMOS contact 161 may be formed inside the NMOS contact trench T1 of FIG. 18, and a PMOS contact 162 may be formed inside the PMOS contact trench T2 of FIG. 18. Through these fabricating processes, the semiconductor device illustrated in FIG. 20 may be fabricated.

A semiconductor device according to other embodiments of the present disclosure will hereinafter be described with reference to FIG. 20, focusing on differences from the semiconductor device illustrated in FIGS. 1 and 2.

FIG. 20 is a cross-sectional view for explaining a semiconductor device according to other embodiments of the present disclosure.

Referring to FIG. 20, in the semiconductor device according to other embodiments of the present disclosure, the lower surface of a second NMOS conductive layer 114 may contact the upper surface of a first NMOS conductive layer 113, and the lower surface of a second PMOS conductive layer 124 may contact the upper surface of a first PMOS conductive layer 123.

For example, a NMOS gate structure 210 may include a NMOS gate insulating layer 111, a first dipole layer 112, a first NMOS conductive layer 113, a second NMOS conductive layer 114, and an NMOS capping layer 117, which are sequentially stacked in the vertical direction DR3 on the upper surface of the portion of a substrate 100 in an NMOS region I. For example, a PMOS gate structure 220 may include a PMOS gate insulating layer 121, a fourth PMOS conductive layer 126, a first PMOS conductive layer 123, a second PMOS conductive layer 124, and a PMOS capping layer 127, which are sequentially stacked in the vertical direction DR3 on the upper surface of the portion of the substrate 100 in a PMOS region II. For example, an NMOS gate spacer 231 may be disposed on both sidewalls of the NMOS gate structure 210 in the first horizontal direction DR1, and a PMOS gate spacer 232 may be disposed on both sidewalls of the PMOS gate structure 220 in the first horizontal direction DR1.

A method for fabricating a semiconductor device according to other embodiments of the present disclosure will hereinafter be described with reference to FIGS. 20 through 27, focusing on differences from the method illustrated in FIGS. 2 through 13.

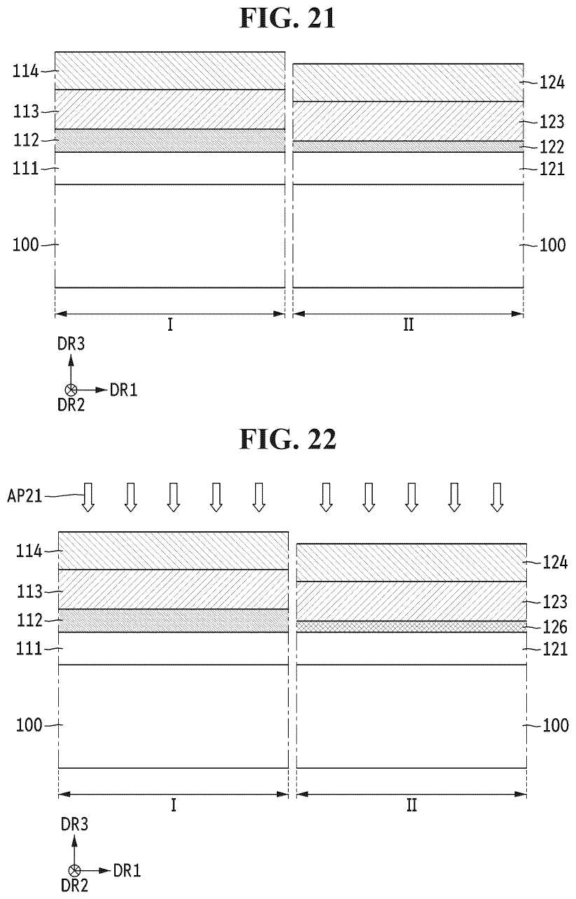

Referring to FIG. 21, after performing the fabricating processes illustrated in FIGS. 3 through 6, a second NMOS conductive layer 114 may be formed on the upper surface of the first NMOS conductive layer 113, and a second PMOS conductive layer 124 may be formed on the upper surface of the first PMOS conductive layer 123. For example, the lower surface of the second NMOS conductive layer 114 may contact the upper surface of the first NMOS conductive layer 113, and the lower surface of the second PMOS conductive layer 124 may contact the upper surface of the first PMOS conductive layer 123.

Referring to FIG. 22, an annealing process AP21 may be performed on the NMOS region I and the PMOS region II. Through the annealing process AP21, a fourth PMOS conductive layer 126 may be formed between the upper surface of the PMOS gate insulating layer 121 and the lower surface of the first PMOS conductive layer 123. For example, through the annealing process AP21, the second dipole layer 122 of FIG. 21 may be transformed into the fourth PMOS conductive layer 126.

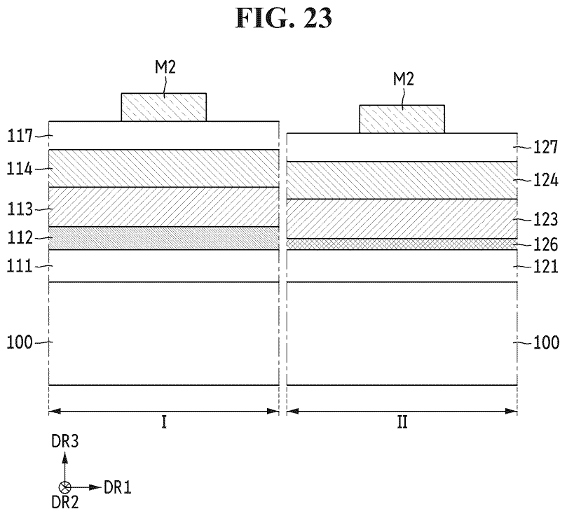

Referring to FIG. 23, an NMOS capping layer 117 may be formed on the upper surface of the second NMOS conductive layer 114, and a PMOS capping layer 127 may be formed on the upper surface of the second PMOS conductive layer 124. Thereafter, a second mask pattern M2 may be formed on the upper surface of each of the NMOS capping layer 117 and the PMOS capping layer 127.

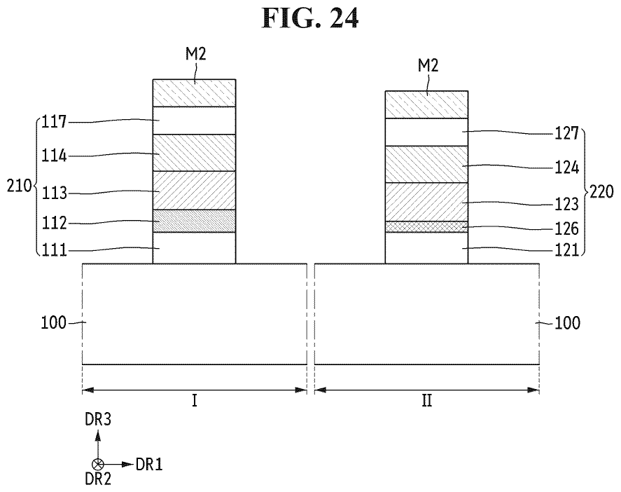

Referring to FIG. 24, a patterning process involving an etching process using the second mask pattern M2 as a mask may be performed. For example, in the NMOS region I, the NMOS gate insulating layer 111, the first dipole layer 112, the first NMOS conductive layer 113, the second NMOS conductive layer 114, and the NMOS capping layer 117 may each be patterned using the second mask pattern M2 as a mask. As a result, an NMOS gate structure 210, which includes the NMOS gate insulating layer 111, the first dipole layer 112, the first NMOS conductive layer 113, the second NMOS conductive layer 114, and the NMOS capping layer 117, may be formed on the upper surface of the portion of the substrate 100 in the NMOS region I.

Similarly, in the PMOS region II, the PMOS gate insulating layer 121, the fourth PMOS conductive layer 126, the first PMOS conductive layer 123, the second PMOS conductive layer 124, and the PMOS capping layer 127 may each be patterned using the second mask pattern M2 as a mask. As a result, a PMOS gate structure 220, which includes the PMOS gate insulating layer 121, the fourth PMOS conductive layer 126, the first PMOS conductive layer 123, the second PMOS conductive layer 124, and the PMOS capping layer 127, may be formed on the upper surface of the portion of the substrate 100 in the PMOS region II.

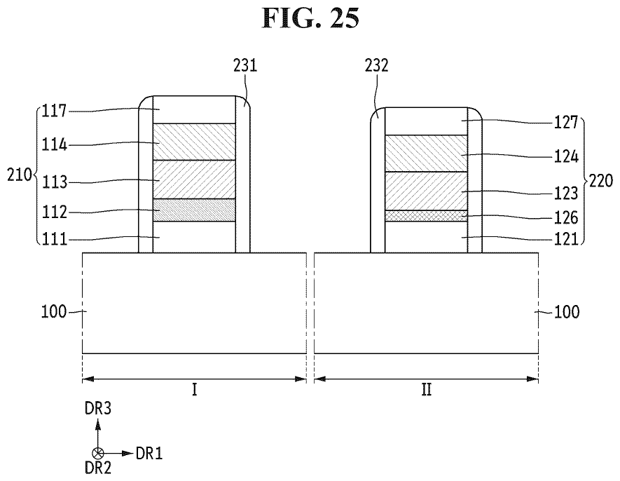

Referring to FIG. 25, the second mask pattern M2 of FIG. 24 may be removed. Thereafter, an NMOS gate spacer 231 may be formed on both sidewalls of the NMOS gate structure 210 in the first horizontal direction DR1, and a PMOS gate spacer 232 may be formed on both sidewalls of the PMOS gate structure 220 in the first horizontal direction DR1.

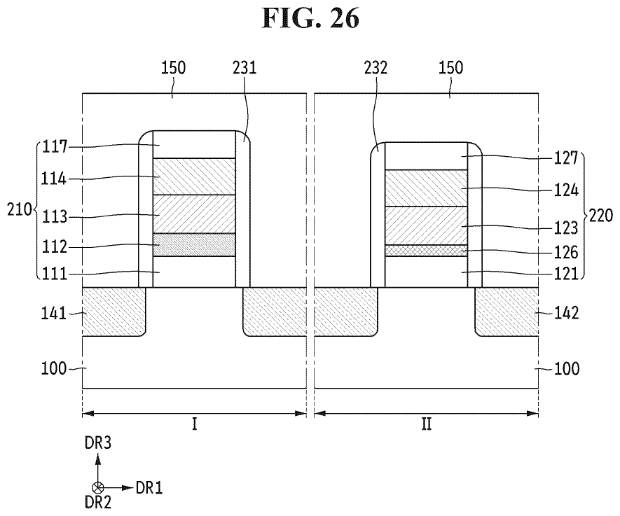

Referring to FIG. 26, an NMOS source/drain region 141 may be formed inside the portion of the substrate 100 in the NMOS region I. The NMOS source/drain region 141 may be formed on both sides of the NMOS gate structure 210 in the first horizontal direction DR1. Similarly, a PMOS source/drain region 142 may be formed inside the portion of the substrate 100 in the PMOS region II. The PMOS source/drain region 142 may be formed on both sides of the PMOS gate structure 220 in the first horizontal direction DR1.

Thereafter, an interlayer insulating layer 150 may be formed on the upper surfaces of the portions of the substrate 100 in the NMOS region I and the PMOS region II. For example, the interlayer insulating layer 150 may cover the upper surface of each of the NMOS source/drain region 141 and the PMOS source/drain region 142. The interlayer insulating layer 150 may surround the sidewalls of each of the NMOS gate spacer 231 and the PMOS gate spacer 232. The interlayer insulating layer 150 may also cover the upper surface of each of the NMOS gate structure 210 and the PMOS gate structure 220.

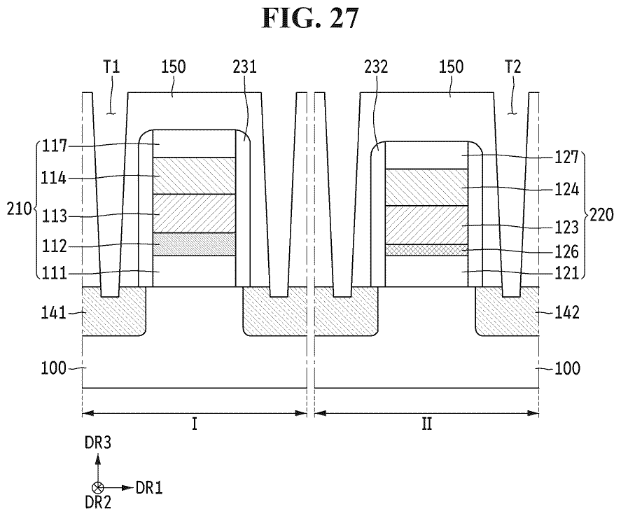

Referring to FIG. 27, an NMOS contact trench T1, which exposes the NMOS source/drain region 141, may be formed by vertically penetrating the portion of the interlayer insulating layer 150 in the NMOS region I. Similarly, a PMOS contact trench T2, which exposes the PMOS source/drain region 142, may be formed by vertically penetrating the portion of the interlayer insulating layer 150 in the PMOS region II.

Referring again to FIG. 20, an NMOS contact 161 may be formed inside the NMOS contact trench T1 of FIG. 27, and a PMOS contact 162 may be formed inside the PMOS contact trench T2 of FIG. 27. Additionally, an NMOS silicide layer 171 may be formed along the interface between the NMOS source/drain region 141 and the NMOS contact 161, and a PMOS silicide layer 172 may be formed along the interface between the PMOS source/drain region 142 and the PMOS contact 162. Through these fabricating processes, the semiconductor device illustrated in FIG. 20 may be fabricated.

Although embodiments of the present disclosure have been described with reference to the accompanying drawings, the present disclosure is not limited to the described embodiments. Various modifications and alterations can be made without departing from the technical spirit or essential features of the present disclosure by those skilled in the art to which the present disclosure pertains. Therefore, the described embodiments should be understood as illustrative rather than restrictive in all respects.

What is claimed is:

1. A method for fabricating a semiconductor device, comprising:
providing a substrate;
forming a first dipole layer on an upper surface of the substrate;
etching a portion of the first dipole layer, wherein a remaining the first dipole layer is defined as a second dipole layer;
forming a first p-type metal-oxide semiconductor (PMOS) conductive layer on an upper surface of the second dipole layer;
forming a second PMOS conductive layer on an upper surface of the first PMOS conductive layer; and
forming a fourth PMOS conductive layer by performing an annealing process to transform the second dipole layer between the upper surface of the substrate and a lower surface of the first PMOS conductive layer,
wherein the fourth PMOS conductive layer includes a material different from a material of the second dipole layer.

2. The method of claim 1, wherein the forming the fourth PMOS conductive layer comprises:
forming the fourth PMOS conductive layer by performing the annealing process to nitride the second dipole layer.

3. The method of claim 1, wherein a thickness of the second dipole layer in a vertical direction is smaller than a thickness of the first dipole layer in the vertical direction.

4. The method of claim 1, wherein the forming the first dipole layer comprises:
forming a PMOS gate insulating layer on the upper surface of the substrate; and
forming the first dipole layer on an upper surface of the PMOS gate insulating layer.

5. The method of claim 1, further comprising:
after the forming the fourth PMOS conductive layer,
forming a PMOS gate structure by patterning each of the fourth PMOS conductive layer, the first PMOS conductive layer and the second PMOS conductive layer.

6. The method of claim 1, further comprising:
after the forming the fourth PMOS conductive layer,
forming a PMOS capping layer on an upper surface of the second PMOS conductive layer.

7. The method of claim 1, wherein the forming the fourth PMOS conductive layer comprises:
patterning each of the second dipole layer, the first PMOS conductive layer and the second PMOS conductive layer; and
forming the fourth PMOS conductive layer by performing the annealing process to transform the second dipole layer.

8. The method of claim 7, wherein the forming the fourth PMOS conductive layer comprises:
after the patterning each of the second dipole layer, the first PMOS conductive layer and the second PMOS conductive layer,
forming a PMOS source/drain region inside the substrate;
forming an interlayer insulating layer on the PMOS source/drain region;
forming a PMOS contact trench penetrating the interlayer insulating layer in a vertical direction to extend into the PMOS source/drain region; and
forming a PMOS silicide layer by performing the annealing process to transform a portion of the PMOS source/drain region exposed through the PMOS contact trench.

9. The method of claim 1, wherein the forming the second PMOS conductive layer comprises:
forming a PMOS sacrificial layer on the upper surface of the first PMOS conductive layer; and
forming the second PMOS conductive layer on an upper surface of the PMOS sacrificial layer.

10. The method of claim 9, wherein the forming the fourth PMOS conductive layer comprises:
forming a third PMOS conductive layer by performing the annealing process to transform the PMOS sacrificial layer between the upper surface of the first PMOS conductive layer and a lower surface of the second PMOS conductive layer.

11. The method of claim 10, wherein the forming the third PMOS conductive layer comprises:
forming the third PMOS conductive layer by performing the annealing process to silicidize the PMOS sacrificial layer.

12. A method for fabricating a semiconductor device, comprising:
providing a substrate including an n-type metal-oxide semiconductor (NMOS) region and a p-type metal-oxide semiconductor (PMOS) region;
forming a first dipole layer on an upper surface of the substrate in each of the NMOS region and the PMOS region;
etching a portion of the first dipole layer in the PMOS region, wherein a remaining the first dipole layer in the PMOS region is defined as a second dipole layer;
forming a first NMOS conductive layer on an upper surface of the first dipole layer in the NMOS region, and forming a first PMOS conductive layer on an upper surface of the second dipole layer in the PMOS region;
forming a second NMOS conductive layer on an upper surface of the first NMOS conductive layer, and forming a second PMOS conductive layer on an upper surface of the first PMOS conductive layer; and
forming a fourth PMOS conductive layer by performing an annealing process to transform the second dipole layer between the upper surface of the substrate and a lower surface of the first PMOS conductive layer,
wherein the fourth PMOS conductive layer includes a material different from a material of the second dipole layer,
wherein the first NMOS conductive layer and the first PMOS conductive layer include the same material, and
wherein the second NMOS conductive layer and the second PMOS conductive layer include the same material.

13. The method of claim 12, wherein the first dipole layer in the NMOS region remains untransformed during the forming the fourth PMOS conductive layer.

14. The method of claim 12, wherein a thickness of the second PMOS conductive layer in a vertical direction is the same as a thickness of the second NMOS conductive layer in the vertical direction, and
wherein an upper surface of the second PMOS conductive layer is formed lower than an upper surface of the second NMOS conductive layer.

15. The method of claim 12, further comprising:
after the forming the fourth PMOS conductive layer,
forming a PMOS gate structure by patterning each of the fourth PMOS conductive layer, the first PMOS conductive layer and the second PMOS conductive layer, and forming an NMOS gate structure by patterning each of the first dipole layer, the first NMOS conductive layer and the second NMOS conductive layer.

16. The method of claim 15, further comprising:
after the forming the NMOS gate structure and the PMOS gate structure,
forming an NMOS gate spacer in contact with sidewalls of each of the fourth PMOS conductive layer, the first PMOS conductive layer and the second PMOS conductive layer, and forming a PMOS gate spacer in contact with sidewalls of each of the first dipole layer, the first NMOS conductive layer and the second NMOS conductive layer.

17. The method of claim 12, wherein the forming each of the second NMOS conductive layer and the second PMOS conductive layer comprises:
forming an NMOS sacrificial layer on the upper surface of the first NMOS conductive layer, and forming a PMOS sacrificial layer on the upper surface of the first PMOS conductive layer; and
forming the second NMOS conductive layer on an upper surface of the NMOS sacrificial layer, and forming the second PMOS conductive layer on an upper surface of the PMOS sacrificial layer.

18. The method of claim 17, wherein the forming the fourth PMOS conductive layer comprises:
forming a third NMOS conductive layer by performing the annealing process to transform the NMOS sacrificial layer between the upper surface of the first NMOS conductive layer and a lower surface of the second NMOS conductive layer, and forming a third PMOS conductive layer by performing the annealing process to transform the PMOS sacrificial layer between the upper surface of the first PMOS conductive layer and a lower surface of the second PMOS conductive layer.

19. A semiconductor device comprising:
a substrate including an n-type metal-oxide semiconductor (NMOS) region and a p-type metal-oxide semiconductor (PMOS) region;
an NMOS gate structure including an NMOS gate insulating layer, a first dipole layer, a first NMOS conductive layer, a second NMOS conductive layer and an NMOS capping layer sequentially stacked in a vertical direction on an upper surface of the substrate in the NMOS region; and
a PMOS gate structure including a PMOS gate insulating layer, a fourth PMOS conductive layer, a first PMOS conductive layer, a second PMOS conductive layer and a PMOS capping layer sequentially stacked in the vertical direction on an upper surface of the substrate in the PMOS region,
wherein the first NMOS conductive layer and the first PMOS conductive layer include the same material,
wherein the second NMOS conductive layer and the second PMOS conductive layer include the same material,
wherein a thickness of the fourth PMOS conductive layer in the vertical direction is smaller than a thickness of the first dipole layer in the vertical direction,
wherein a thickness of the first PMOS conductive layer in the vertical direction is the same as a thickness of the first NMOS conductive layer in the vertical direction,
wherein a thickness of the second PMOS conductive layer in the vertical direction is the same as a thickness of the second NMOS conductive layer in the vertical direction, and
wherein an upper surface of the PMOS gate structure is formed lower than an upper surface of the NMOS gate structure.

20. The semiconductor device of claim 19, wherein the NMOS gate structure further includes a third NMOS conductive layer disposed between an upper surface of the first NMOS conductive layer and a lower surface of the second NMOS conductive layer,
wherein the PMOS gate structure further includes a third PMOS conductive layer disposed between an upper surface of the first PMOS conductive layer and a lower surface of the second PMOS conductive layer,
wherein the third NMOS conductive layer and the third PMOS conductive layer include the same material, and
wherein an upper surface of the third PMOS conductive layer is formed lower than an upper surface of the third NMOS conductive layer.
